(19) United States
(12) Patent Application Publication
(10) Pub. No.: US 2014/0213054 A1
(43) Pub. Date: Jul. 31, 2014

(54) EXPOSING METHOD AND METHOD OF FORMING A PATTERN USING THE SAME

(71) Applicant: SAMSUNG ELECTRONICS CO., LTD., Suwon-si (KR)

(72) Inventors: In-Sung KIM, Seongnam-si (KR); Chang-Min PARK, Seongnam-si (KR); Jeong-Ho YEO, Suwon-si (KR)

(73) Assignee: SAMSUNG ELECTRONICS CO., LTD., Suwon-si (KR)

(21) Appl. No.: 14/167,055

(22) Filed: Jan. 29, 2014

(30) Foreign Application Priority Data
Jan. 29, 2013 (KR) 10-2013-0009728

(51) Int. Cl. H01L 21/308

(52) U.S. Cl. CPC H01L 21/3088; H01L 21/3086
USPC 438/689; 355/77

(57) ABSTRACT

An exposing method includes irradiating a first light having a first energy to a first exposed region of a photoresist film through a first shot region of a mask, and irradiating a second light having a second energy to the first exposed region of the photoresist film through a second shot region of the mask.

### CROSS-REFERENCE TO RELATED APPLICATION

Korean Patent Application No. 10-2013-009728, filed on Jan. 29, 2013, in the Korean Intellectual Property Office, and entitled: “Exposing Method and Method of Forming A Pattern Using the Same,” is incorporated by reference herein in its entirety.

### BACKGROUND

1. Field

Example embodiments relate to an exposing method and a method of forming a pattern using the same.

2. Description of the Related Art

Generally, an exposing process may include transcribing a pattern of a mask into a photoresist film to form a photoresist pattern. Therefore, a layer may be etched using the photoresist pattern as an etch mask to form a pattern on a semiconductor substrate. Thus, a shape of the pattern on the semiconductor substrate may be determined in accordance with the shape of the mask. Particularly, a critical dimension (CD) uniformity of the pattern may be dependent upon a CD uniformity of the mask pattern.

### SUMMARY

Example embodiments provide an exposing method capable of forming a photoresist pattern having improved CD uniformity.

Example embodiments also provide a method of forming a pattern using a photoresist pattern with improved CD uniformity.

According to some example embodiments, there is provided an exposing method including irradiating a first light having a first energy to a first exposed region of a photoresist film through a first shot region of a mask, and irradiating a second light having a second energy to the first exposed region of the photoresist film through a second shot region of the mask.

A sum of the first energy and the second energy may equal a total energy required to completely expose the first exposed region of the photoresist film.

The first energy and the second energy may be substantially the same.

The method may further include shifting the mask to position the second shot region over the first exposed region.

The method may further include irradiating a third light having a third energy to the first exposed region of the photoresist film through a third shot region of the mask.

A sum of the first energy, the second energy, and the third energy may equal a total energy required to completely expose the first exposed region of the photoresist film.

The first energy, the second energy, and the third energy may equal each other.

The method may further include irradiating the first light having the first energy to a second exposed region of the photoresist film through the first shot region of the mask, and irradiating the second light having the second energy to the second exposed region of the photoresist film through the second shot region of the mask.

The first light and the second light may include an extreme ultraviolet (EUV) light.

According to some other example embodiments, there is provided an exposing method including irradiating a first light having a first energy to a photoresist film through shot regions of a mask, shifting the mask, irradiating a second light having a second energy to the photoresist film through the shot regions of the mask, developing the photoresist film to form a photoresist pattern, and etching a layer using the photoresist pattern as an etch mask to form the pattern.

A sum of the first energy and the second energy may equal a total energy required to completely expose the photoresist film.

The first energy and the second energy may equal each other.

According to yet some other example embodiments, there is provided an exposing method including positioning a mask over a photoresist film, the mask including a plurality of shot regions, irradiating a first light having a first energy to at least a first exposed region of the photoresist film through a first shot region of the mask, and irradiating a second light having a second energy to the at least first exposed region of the photoresist film through a second shot region of the mask, such that substantially the same region of the photoresist film is irradiated through different shot regions of the mask.

A sum of the first energy and the second energy may equal a total energy required to completely expose the first exposed region of the photoresist film.

The first energy and the second energy may equal each other.

A shape of the first exposed region, after the first and second irradiations, may equal an average shape of the first and second shot regions of the mask.

The method may further include sequentially irradiating the first and second lights through respective first and second shot regions onto each exposure region of the photoresist film, such that a shape of each exposure region of the photoresist film equals the average shape of the first and second shot regions of the mask.

The method may further include irradiating at least a third light having a third energy to the at least first exposed region of the photoresist film through a third shot region of the mask, such that substantially the same region of the photoresist film is irradiated through all the shot regions of the mask by respective different lights, wherein a sum of energy of all the different lights equals a total energy required to completely expose each exposed region of the photoresist film.

### BRIEF DESCRIPTION OF THE DRAWINGS

Example embodiments will be more clearly understood from the following detailed description taken in conjunction with the accompanying drawings. FIGS. 1 to 7 represent non-limiting, example embodiments as described herein.

FIGS. 1A to 3A illustrate perspective views of stages in an exposing method in accordance with example embodiments;

FIGS. 1B to 3B illustrate cross-sectional views of positions of a mask and a photoresist film exposed by the exposing method in FIGS. 1A to 3A; and

FIGS. 4 to 7 illustrate cross-sectional views of stages in a method of forming a pattern using a photoresist pattern formed by the exposing method in FIGS. 1A to 3A.

### DETAILED DESCRIPTION

Various example embodiments will be described more fully hereinafter with reference to the accompanying drawings, in which some example embodiments are shown. Example embodiments may, however, be embodied in many different forms and should not be construed as limited to those described herein. Rather, these example embodiments are provided so that this disclosure will be thorough and complete, and will fully convey exemplary implementations to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

Exposing Method

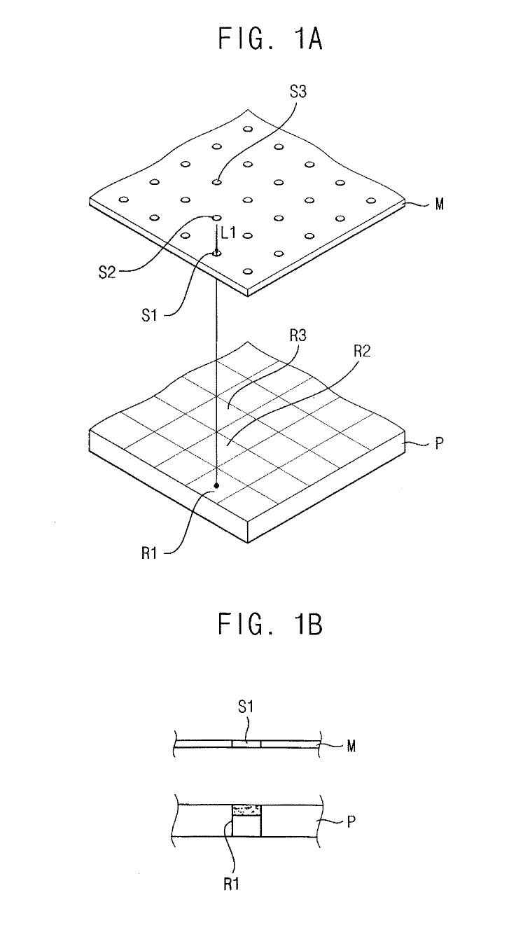

FIGS. 1A to 3A illustrate perspective views of stages in an exposing method in accordance with example embodiments, and FIGS. 1B to 3B illustrate cross-sectional views of positions of a mask and a photoresist film exposed by the exposing method in FIGS. 1A to 3A.

Referring to FIGS. 1A and 1B, a mask M may be arranged over a photoresist film P. In example embodiments, the mask M may have a plurality of shot regions. The shot regions may be arranged lengthwisely and breadthwisely by substantially the same interval, e.g., to have a matrix pattern. For example, the shot regions may include a first shot region S1, a second shot region S2, and a third shot region S3 in a diagonal direction of the mask M, i.e., along a direction at an oblique angle with respect to either side of the mask M. The first shot region S1, the second shot region S2, and the third shot region S3 may have slightly different sizes. As illustrated in FIG. 1A, each of the shot regions in the mask M may include an opening, i.e., a hole, through the mask M.

The photoresist film P may have exposed regions corresponding to the shot regions of the mask M. In example embodiments, the exposed regions may include a first exposed region R1, a second exposed region R2, and a third exposed region R3 in a diagonal direction of the photoresist film P, i.e., along a direction at an oblique angle with respect to either side of the photoresist film P. The first exposed region R1 may be positioned to correspond to the first shot region S1. The second exposed region R2 may be positioned to correspond to the second shot region S2. The third exposed region R3 may be positioned to correspond to the third shot region S3.

Referring to FIG. 1A, a first light L1 may be irradiated to the first exposed region R1 through the first shot region S1. In example embodiments, the first light L1 passing through the first shot region S1 may be reduced, e.g., relative to a total amount of light required for totally exposing the photoresist film P. The reduced first light L1 may be irradiated to the first exposed region R1.

In detail, a total amount of light required for totally exposing the photoresist film P may have a total energy ET. The first light L1 may have a first energy, e.g., the first energy may be about ⅓ of the total energy ET. For example, the first light L1 may have a dose of about ⅓ of a total dose of the total amount of light having the total energy ET. Thus, the first light L1 may have a total number of photons that equals about ⅓ of a total number of photons in the total light having the total energy ET. As shown in FIG. 1B, a ⅓ portion of the first exposed region R1, e.g., along the thickness direction of the photoresist film P, may be exposed by the first light L1. Particularly, the first exposed region R1 having the exposed ⅓ portion may have a shape corresponding to a shape of the first shot region S1, e.g., the first shot region S1 and the first exposed region R1 may completely overlap each other.

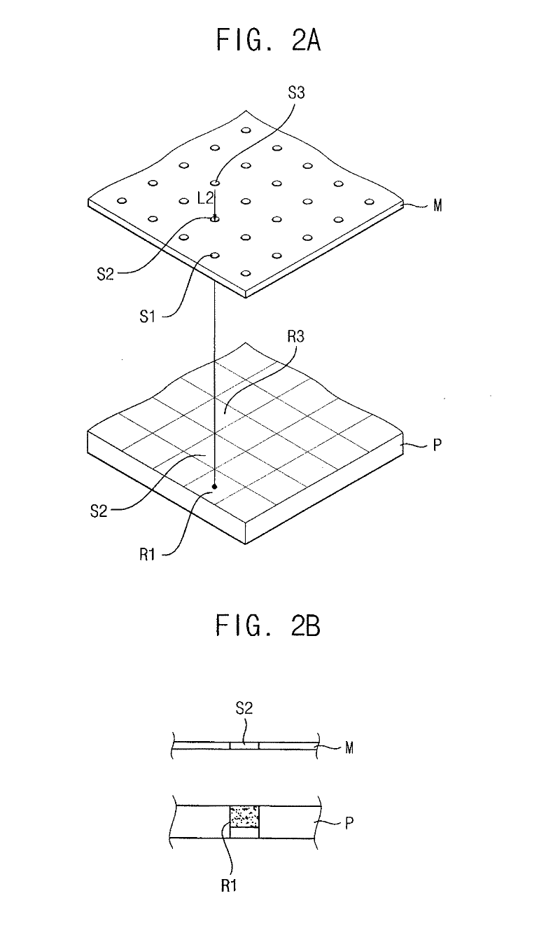

Referring to FIGS. 2A and 2B, the mask M may be shifted in the diagonal direction to position the second shot region S2 over the first exposed region R1. Alternatively, the photoresist film P may be shifted to position the second shot region S2 over the first exposed region R1.

Referring to FIG. 2A, a second light L2 may be irradiated to the first exposed region R1 through the second shot region S2. In example embodiments, the second light L2 passing through the second shot region S2 may be reduced. The reduced second light L2 may be irradiated to the first exposed region R1.

In example embodiments, the second light L2 may have a second energy. The second energy may be about ⅓ of the total energy ET. That is, the second energy may be substantially the same as the first energy. As shown in FIG. 2B, a ⅓ portion of the first exposed region R1 may be exposed by the second light L2. As a result, a ⅔ portion of the first exposed region R1 may be exposed by the first light L1 and the second light L2, i.e., a combined portion of the first exposed region R1 exposed by the first and second lights L1 and L2 is ⅔ of the first exposed region R1. Particularly, the first exposed region R1 having the exposed ⅔ portion may have a shape corresponding to shapes of the first shot region S1 and the second shot region R2.

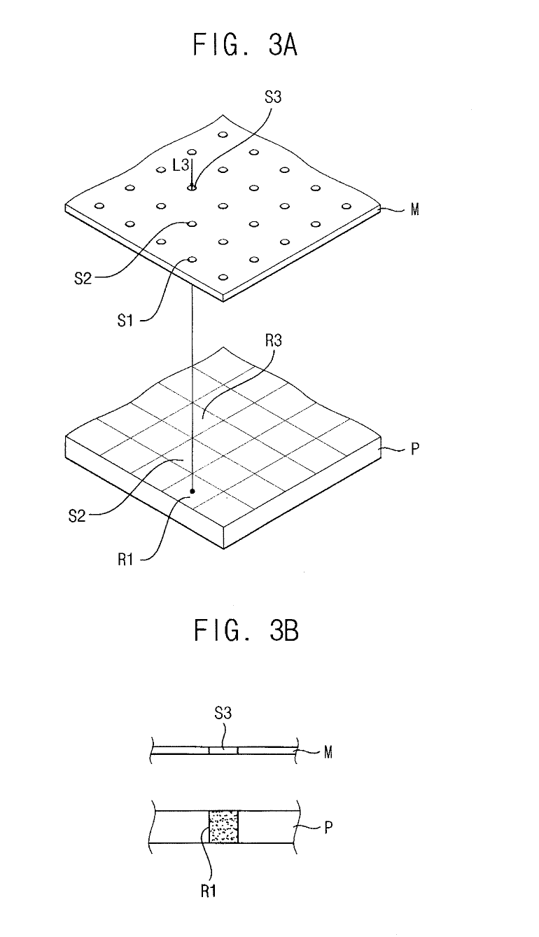

Referring to FIGS. 3A and 3B, the mask M may be shifted in the diagonal direction to position the third shot region S3 over the first exposed region R1. Alternatively, the photoresist film P may be shifted to position the third shot region S3 over the first exposed region R1.

Referring to FIG. 3A, a third light L3 may be irradiated to the first exposed region R1 through the third shot region S3. In example embodiments, the third light L3 passing through the third shot region S3 may be reduced. The reduced third light L3 may be irradiated to the first exposed region R1.

In example embodiments, the third light L3 may have a third energy. The third energy may be about ⅓ of the total energy ET. That is, the third energy may be substantially the same as the first energy. Thus, a sum of the first energy, the second energy, and the third energy may substantially equal the total energy ET. The first light L1, the second light L2, and the third light L3 may include an extreme ultraviolet (EUV) light.

As shown in FIG. 3B, a ⅓ portion of the first exposed region R1 may be exposed by the third light L3. As a result, the first exposed region R1 may be totally exposed, i.e., along a thickness direction, by the first light L1, the second light L2, and the third light L3. Particularly, the first exposed region R1 exposed by the first to third light L1, L2, and L3 may have a shape corresponding to shapes of the first shot region S1, the second shot region R2, and the third shot region S3. Therefore, the first shot region R1 may have an average shape of shapes of the first shot region S1, the second shot region S2, and the third shot region S3. This exposing method may be referred to as a shifted and averaged multiple exposure.

Above-mentioned processes may be performed on the second exposed region R2 and the third exposed region R3. The second exposed region R2 may have an average shape of the shapes of the first shot region S1, the second shot region S2, and the third shot region S3. The third exposed region R3 may have an average shape of the shapes of the first shot region S1, the second shot region S2, and the third shot region S3. Therefore, the first exposed region R1, the second exposed region R2, and the third exposed region R1 may have substantially the same shape so that the first exposed region R1, the second exposed region R2, and the third exposed region R3 may have improved CD uniformity. As a result, the exposing method of this example embodiment may improve the CD uniformity of the photoresist pattern.

In example embodiments, the mask may be shifted in the diagonal direction. Alternatively, the mask may be shifted in a horizontal direction.

In example embodiments, the exposing method may be applied to the three shot regions and the three exposed regions. Alternatively, the exposing method may be applied to at least two shot regions and at least two exposed regions to improve the CD uniformity of the photoresist pattern. That is, the CD uniformity of the photoresist pattern may be improved by applying the total shot regions of the mask to one exposed region of the photoresist film.

Method of Forming a Pattern

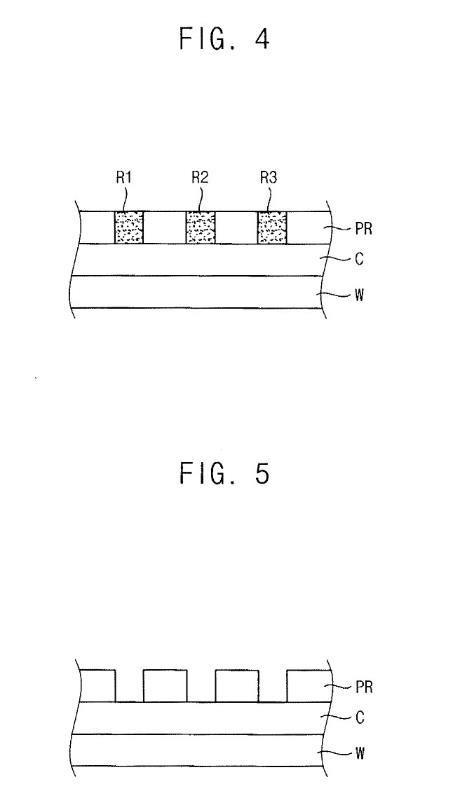

FIGS. 4 to 7 illustrate cross-sectional views of stages in a method of forming a pattern using a photoresist pattern formed by the exposing method in FIGS. 1A to 3A.

Referring to FIG. 4, a layer C may be formed on an upper surface of a semiconductor substrate W. A photoresist pattern PR formed by the above-mentioned processes illustrated with reference to FIGS. 1A to 3B may be formed on an upper surface of the layer C.

Referring to FIG. 5, a developing solution may be applied to the photoresist pattern PR to remove the exposed regions R1, R2, and R3. Thus, the photoresist pattern PR may have contact holes configured to expose portions of the upper surface the layer C.

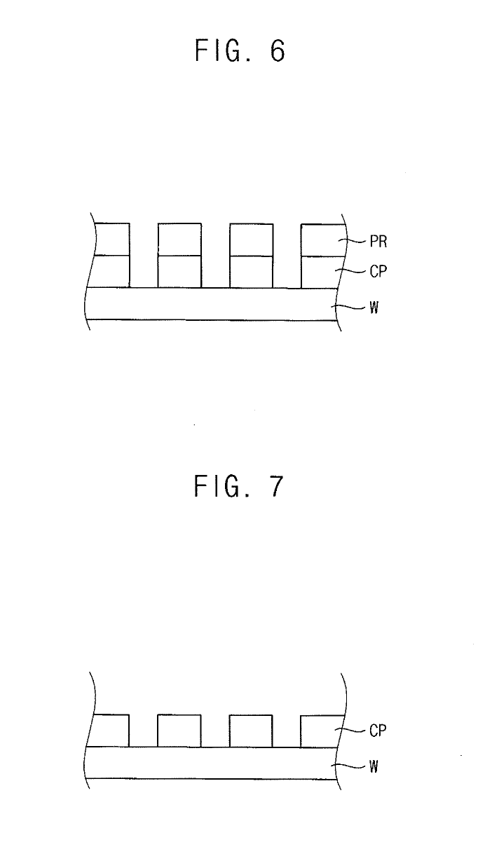

Referring to FIG. 6, the layer C may be etched using the photoresist pattern PR as an etch mask to form a pattern CP. In example embodiments, because the photoresist pattern PR may have a uniform CD, the pattern CP formed using the photoresist pattern PR may also have uniform CD.

Referring to FIG. 7, the photoresist pattern PR may be removed by an ashing process and/or a stripping process.

In example embodiments, the exposing method may be applied to form the pattern CP with the contact holes. Alternatively, the exposing method may be applied to patterns having other shapes.

According to example embodiments, a total energy required for exposing a region of a photoresist film may be equally divided to multiple parts. The divided energy may be provided to the region of the photoresist film by a plurality of lights, such that the number of lights equals the number of multiple parts of the divided energy. The plurality of lights may be irradiated to a same exposed region of the photoresist film through multiple shot regions of a mask, so the same exposed region is exposed to the total energy required for exposing the exposed region. As the shape of the exposed region may have a shape corresponding to an average shape of the multiple shot regions, and as all of the exposed regions of the photoresist pattern may have the average shape of the multiple shot regions, the photoresist pattern may have an increased critical dimension (CD) uniformity. As a result, as CD uniformity of a pattern depends on a CD uniformity of the photoresist pattern, the pattern formed using the photoresist pattern having the uniform CD may also have uniform CD. In contrast, when shot regions of a mask are not identical, i.e., slightly different in size, and are used to form only separate respective exposure regions, i.e., rather than form a same exposure region with a shape corresponding to an average shape of the shot regions, uniformity of the CD of the mask and pattern may be reduced.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present invention. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, all such modifications are intended to be included within the scope of the present invention as defined in the claims.

What is claimed is:

1. An exposing method, the method comprising:
irradiating a first light having a first energy to a first exposed region of a photoresist film through a first shot region of a mask; and
irradiating a second light having a second energy to the first exposed region of the photoresist film through a second shot region of the mask.

2. The method as claimed in claim 1, wherein a sum of the first energy and the second energy equals a total energy required to completely expose the first exposed region of the photoresist film.

3. The method as claimed in claim 2, wherein the first energy and the second energy are substantially the same.

4. The method as claimed in claim 1, further comprising shifting the mask to position the second shot region over the first exposed region.

5. The method as claimed in claim 1, further comprising irradiating a third light having a third energy to the first exposed region of the photoresist film through a third shot region of the mask.

6. The method as claimed in claim 5, wherein a sum of the first energy, the second energy, and the third energy equals a total energy required to completely expose the first exposed region of the photoresist film.

7. The method as claimed in claim 6, wherein the first energy, the second energy, and the third energy equal each other.

8. The method as claimed in claim 1, further comprising:
irradiating the first light having the first energy to a second exposed region of the photoresist film through the first shot region of the mask; and
irradiating the second light having the second energy to the second exposed region of the photoresist film through the second shot region of the mask.

9. The method as claimed in claim 1, wherein the first light and the second light include an extreme ultraviolet (EUV) light.

10. A method of forming a pattern, the method comprising:
irradiating a first light having a first energy to a photoresist film through shot regions of a mask;
shifting the mask;
irradiating a second light having a second energy to the photoresist film through the shot regions of the mask;
developing the photoresist film to form a photoresist pattern; and
etching a layer using the photoresist pattern as an etch mask to form the pattern.

11. The method as claimed in claim 10, wherein a sum of the first energy and the second energy equals a total energy required to completely expose the photoresist film.

12. The method as claimed in claim 11, wherein the first energy and the second energy equal each other.

13. An exposing method, the method comprising:
positioning a mask over a photoresist film, the mask including a plurality of shot regions;
irradiating a first light having a first energy to at least a first exposed region of the photoresist film through a first shot region of the mask; and
irradiating a second light having a second energy to the at least first exposed region of the photoresist film through a second shot region of the mask, such that substantially the same region of the photoresist film is irradiated through different shot regions of the mask.

14. The method as claimed in claim 13, wherein a sum of the first energy and the second energy equals a total energy required to completely expose the first exposed region of the photoresist film.

15. The method as claimed in claim 14, wherein the first energy and the second energy equal each other.

16. The method as claimed in claim 13, wherein a shape of the first exposed region, after the first and second irradiations, equals an average shape of the first and second shot regions of the mask.

17. The method as claimed in claim 16, further comprising sequentially irradiating the first and second lights through respective first and second shot regions onto each exposure region of the photoresist film, such that a shape of each exposure region of the photoresist film equals the average shape of the first and second shot regions of the mask.

18. The method as claimed in claim 16, further comprising irradiating at least a third light having a third energy to the at least first exposed region of the photoresist film through a third shot region of the mask, such that substantially the same region of the photoresist film is irradiated through all the shot regions of the mask by respective different lights, wherein a sum of energy of all the different lights equals a total energy required to completely expose each exposed region of the photoresist film.
